(19) United States
(12) Patent Application Publication
(10) Pub. No.: US 2003/0151419 A1
(43) Pub. Date: Aug. 14, 2003

(54) Contact probe for a testing head

(75) Inventors: Stefano Felici, Robbiate (IT); Giuseppe Crippa, Merate (IT)

Correspondence Address: SEED INTELLECTUAL PROPERTY LAW GROUP PLLC, 701 FIFTH AVE, SUITE 6300, SEATTLE, WA, 98104-7092, US

(73) Assignee: Technoprobe S.r.l., Cernusco Lombardone (IT)

(21) Appl. No.: 10/313,908

(22) Filed: Dec. 5, 2002

(30) Foreign Application Priority Data
Dec. 6, 2001 (IT) MI2001A002574

(51) Int. Cl. G01R 31/02

(52) U.S. Cl. 324/754

(57) ABSTRACT

A contact probe for a testing head is described. The probe has at least a pointed rod-shaped body having a crook-shaped section capable to contact mechanically and electrically at least one contact pad of an electronic device to be tested and defined form an elbow point on the rod-shaped body. The rod-shaped body comprises at least one additional elbow point spaced form the elbow point and defining a concave angle in the rod-shaped body.

### BACKGROUND OF THE INVENTION

1. Field of the Invention

The present invention relates to a contact probe for a testing head and more particularly to a probe for a testing head suitable for testing semiconductor integrated devices.

2. Description of the Related Art

As it is well known, a testing head is basically a device suitable to electrically interconnect a plurality of contact pads of a microstructure and the corresponding channels of a testing machine that is to perform the tests.

Integrated circuits are factory tested in order to spot and reject any circuits which are already defective during the production phase. The testing heads are normally employed to electrically test the integrated circuits “on wafer,” prior to cutting and mounting them in a chip package.

A large use is made of the so-called cantilever testing heads, i.e., testing heads comprising a plurality of probes projecting in a cantilever way from a suitable holder.

More particularly, as schematically shown in FIGS. 1 and 2, a testing head 1 having cantilever probes usually comprises a backing ring 2, made of aluminum, ceramics or other suitable materials, to which a resin holder 3 is attached, and that is suitable to hold a plurality of movable contact elements or contact probes 4, being normally wires made of special alloys having good electrical and mechanical properties, the probes being mounted to jut out of the resin holder 3 at plural points 5 and at a suitable angle from a plane β. Such emerging probes are commonly known as “cantilever probes.”

In particular, each contact probe 4 has an end portion or contact tip 6, which is bent with a suitable angle γ from the probe axis so that a plurality of contact pads 7 of a device to be tested is contacted. The bent contact tips 6 are commonly referred to as the “crooks.”

The good connection of the contact probes 4 of the testing head 1 to the contact pads 7 of a device to be tested is ensured by the testing head 1 exerting a pressure on the device, whereby the contact probes 4 are vertically flexed in the opposite direction from the device movement towards the testing head 1.

As schematically shown in FIG. 3 for a single contact probe 4, as the device to be tested vertically moves against the contact crook 6, the contact probe 4 flexes, and its elbow point X, situated at the transition from the contact crook 6 to a probe section 8 emerging from the resin holder 3, describes a circular arc.

Thus, the jutting probe section 8 forms a working arm of the contact probe 4 adapted to flex vertically, and is commonly referred to as “free length.”

The crooked shape of the contact probes 4 is designed to allow the contact crooks 6 of the probes 4 to skid, upon coming in touch with the contact pads 7 of the device to be tested and during the pad overtravel beyond a pre-set point of contact, across the contact pads 7 along a direction dictated by the arrangement geometry.

It should be noted that the force exerted on the contact pads 7 by each contact probe 4 depends on many factors, among which are especially the type of material forming the contact probe 4, the probe shape, the angle α made by the probe contact crook 6, the length of the probe jutting section or free length 8, and the amount of overtravel of the pads to be measured. These factors also determine the extent of the contact crooks 6 skidding on the contact pads 7, this being commonly known as the “scrub.”

Also known in this field is to use backing rings 2, generally made of aluminum, ceramics or other suitable materials, having different shapes depending on the set, of contact pads 7 to be tested, so that the free lengths of the contact probes 4, and hence the forces exerted by the latter to the contact pads 7, can be equalized in the interest of even wear and performance of the testing head 1.

The portions of the contact probes 4 outside the backing ring 2 are usually soldered on a PC board 9, as shown in FIG. 2, to establish an electrical connection between the testing head 1 having cantilever probes and the testing machine.

The known testing heads have inherent limitations in the distance between two adjacent probes, and therefore in the distance between the center of two contact pads of the integrated electronic device to be tested, this distance being known in this field with the English term “pitch.” Particularly, the minimum “pitch” value depends on the geometric layout and the size of the probes. To avoid the contact between adjacent probes, the testing head 1 must comply with the following relation:

X>fc+S

where

X is the pitch value of the device to be tested, i.e., the distance between the center of two adjacent contact pads;

fc is the diameter of the contact probes 4; and

S is the safety distance between adjacent contact probes 4.

The condition S=0, i.e., the safety distance being equal to 0, corresponds to the collision of the probes.

The collision of the probes occurs along the body of the contact probes 4 when they are positioned with parallel axes, as schematically shown in FIG. 4A, or in correspondence with a starting point Y of the contact probes 4 taper when they are positioned with convergent axes, as schematically shown in FIG. 4B.

To increase the probe number, with the same pitch value, present technologies are known to reduce the size of the contact probes 4, and particularly the diameter fc thereof, with a subsequent weakening thereof. Such a solution is thus applicable in a limited number of cases.

It should be noted that, with a dense distribution of the contact pads 7, the contact probes 4 must be arranged in plural rows, and the lengths L1, . . . , Ln of the crooks 6 vary accordingly, as schematically shown in FIG. 5.

The N number of levels required to arrange a plurality of contact probes 4 having diameter fc on contact pads 7 having a distance or pitch equal to X, keeping them at a safety distance S, is calculated through the following empirical formula:

N=(fc+S)/X

In the case of a testing head with cantilever contact probes 4 arranged in a plurality of levels, it appears that the problem of probe collision is tri-dimensional. Particularly, the highest contact risk points are the elbow points of probes having a level corresponding to low tapered areas of the crooks 6 of adjacent contact probes 4.

For convenience of illustration, reference is now made to the embodiment of a testing head 1 of the prior art comprising contact probes 4 arranged on four levels, as schematically shown in FIGS. 6A and 6B.

Particularly, these figures schematically show respective side and front views of a plurality of contact pads 4 arranged on N=4 levels, indicated with L1 . . . L4. The contact probes 4 have thus contact crooks 6 with four different lengths, indicated with I1 . . . I4, attached to the body of the probes 4 in respective elbow points G1 . . . G4.

Known is to alternate the contact probes 4 so that the crooks 6 of adjacent probes 4 are not in progression to each other. In the front view of FIG. 6B it can be thus noted that the sequence of the crooks 6 is L1 followed by L3 followed by L2 followed by L4.

The collision risk between the contact probes 4 can be checked considering the distances between the respective crooks 6 on the planes P1 . . . P4 in correspondence with the elbow points G1 . . . G4.

It appears immediately that the highest collision risk of the configuration shown in FIGS. 6A and 6B is located in correspondence of the elbow point G2 on the plane P2, i.e., of the contact probe of level L2, being the sections of the crooks of the adjacent probes of level L3 and L4 low tapered in correspondence of the plane P2 of the elbow point G2.

In other terms, the probe minimum distance points are between the probe of level L2 and the probe of level L3, as well as between the probe of level L2 and the probe of level L4.

Similarly, it can be verified that the collision risk points, i.e., the minimum distance points, for an arrangement on N=3 levels, are in correspondence with the elbow point G2 of the probe of level L3, i.e., between the probe of level L2 and the probe of level L3, while for an arrangement on N=5 levels they are in correspondence with the elbow point G3 of the probe of level L3, i.e., between the probe of level L3 and the probe of level L4 and between the probe of level L3 and the probe of level L5.

It is therefore convenient, if possible, to arrange the contact probes 4 on the lowest possible number of levels.

In substance, the selection of the arrangement configuration of the contact probes 4 on more levels depend on many factors among which the most relevant are the following:

space available for the whole contact probes 4;

diameter fc of each contact probe 4;

shape of the contact crook 6; and

pitch of the device to be tested.

By setting the pitch value of the device to be tested, it is possible to increase the number of the probes which can be housed in each single level, reducing the diameter thereof.

It is worth noting that contact probes 4 with small diameter have reduced electrical and mechanical performances connected to the increase in the contact resistance between the crooks and the pads of the device to be tested because of the lower pressure exerted by the tips of the contact probes 4 on the respective contact pads 7.

In addition, during the measuring operations on the device to be tested, this device is shifted towards the testing head 1 so that the crook tips of the contact probes abut the corresponding contact pads; once in contact, the movement of the device towards the testing head 1 continues at an extent equal to the so-called preset overtravel in order to ensure a good pressure of the probe tips and, therefore, a good contact resistance Rc between contact probes 4 and contact pads 7 of the device to be tested.

The movement of the tips on the pads causes the etching of the latter and the production of etching marks usually referred to as “scrub marks,” whose length essentially depends on the following parameters:

length In of the crooks 6 of the contact probes 4;

overtravel value;

free-length value of the contact probes 4 and slant angle □ thereof.

A small value of scrub marks means that the testing is not too invasive and it reduces the damages on the contact pads 7 caused by the tips of the contact probes 4, allowing therefore a good quality bonding which is subsequently implemented on these pads to be obtained.

It is therefore worth producing contact probes 4 causing the smallest possible scrub marks.

It can be easily noted that the scrub mark length is highly dependent on the crook length. When the N number of levels increases, involving an increase in the crook length, also the length of the scrub marks associated thereto increases.

Particularly, in a testing head having contact probes 4 on four levels, the probe of level I1, whose crook has a length I1, produces a shorter scrub mark than the probe of level L2, whose crook has a length I2, which scrub mark is in turn shorter than the scrub mark produced by the probe of level L3, whose crook has a length I3.

The probe of the highest level, L4, whose crook has the greatest length, I4, will produce therefore the longest scrub mark, causing, in correspondence therewith, the greatest damages on the contact pads 7.

In addition, it can be easily noted that an increase in the overdrive value results in an improved contact resistance Rc of the probe tips on the contact pads 7 since the probe pressure on these pads increases.

On the contrary, an increase in the overdrive value results in an increased overall scrubbing effect of the contact tips, with the further risk that the tips of the contact probes 4 “skid” outside the area defined by the contact pads 7.

It is possible to try and reduce this skidding risk of the contact probes 4 tips outside the device contact pads 7 by using pads which are elongated in the scrub mark direction, for example by using rectangular contact pads 7, with the longest side arranged along the tip skidding direction, to the detriment of the overall pad area occupation on the device to be tested.

It is finally possible to verify that the scrub mark lengths increase when the elbow angle of the crooks 6 of the contact probe 4 increases and when the free length of the contact probes decreases.

Also known is a testing head comprising a plurality of contact probes 4 arranged in a plurality of levels. Particularly, as shown in FIGS. 7A and 7B, the testing head comprises at least four probes arranges, emerging from an holder 3, on four levels L1, . . . , L4 and having four crooks 61, . . . , 64 respectively.

Particularly, the contact probes 4 comprise a pointed substantially rod-shaped body and have an end portion called crook 6, bent in correspondence with a so-called elbow point, in order to contact a plurality of contact pads 7 of the device 10 being tested, the bonding between the contact probes 4 and these contact pads 7 being ensured by the pressure of the testing head on the device 10. The contact probes 4 flex therefore vertically in the opposite direction from the device movement to the testing head.

The contact probes 4 further have, besides the starting elbow point G1, . . . , G4 of the crooks 6, an additional elbow point Ga1, . . . ,Ga4 located in the probe section between the holder 3 and said crooks. This additional elbow point defines at least one probe section which is bent in the same direction as the crooks 6.

At present, the market trend leads to the design of devices which are more and more dense. It is therefore essential to arrange the probes on more levels, even over the four conventional levels, and to use contact probes which have very small diameter, even less than 100 u, and thus inherently not sufficient to ensure good electrical and mechanical performances.

Unfortunately, the need to arrange the probes on several levels contrasts with the need to limit or even reduce the scrub mark length, and consequently the contact pad 7 damage and the skidding risk, mainly because the contact pads 7 size tends to be constantly reduced.

By using contact pads 7 having an elongated shape, for example rectangular, it is possible to accept higher scrub mark values and therefore a higher pressure, improving the contact between the contact probes 4 and the contact pads 7, and avoiding in the meantime the tip skidding outside the contact area of the pads 7, particularly for the tips of the highest level probes, which cause the longest scrub marks.

This solution can be considered only partial and not very suitable due to the area waste on the device to be tested.

In addition, the increase in the number of levels leads to an increase in the collision risk between the highest levels since also the minimum distance therewith is proportionally reduced.

As it appears from the above, there are opposite needs requiring very precarious compromise solutions which endanger, even seriously, the good operation of the testing heads 1 according to the prior art.

The features and advantages of a contact probe according to the invention will be apparent from the following description of embodiments thereof, given by way of non-limiting examples with reference to the accompanying drawings.

### BRIEF SUMMARY OF THE INVENTION

Embodiments of the invention provide a contact probe for a microstructure testing head having a configuration which is capable to reduce the area occupation of the testing head as well as the tip scrub on the contact pads, always ensuring a suitable mechanical and electrical contact between the probes and the contact pads.

Presented is a contact probe comprising at least one additional elbow point between an emerging point of the probe from an holder and the elbow point defining the crook, such an additional elbow point having a curvature which is opposite with respect to the curvature of the elbow point defining the crook.

The characteristics and advantages of the contact probe according to the invention will be apparent from the following description of embodiments thereof, given by way of non-limiting examples with reference to the accompanying drawings.

### BRIEF DESCRIPTION OF THE SEVERAL VIEWS OF THE DRAWINGS

FIG. 1 is a top plan view of a testing head having cantilever probes, according to the prior art;

FIG. 2 is a sectional view of the testing head having cantilever probes of FIG. 1;

FIG. 3 is a sectional view of a detail of the testing head having cantilever probes of FIG. 1;

FIGS. 4A and 4B are respective top plan views of further embodiments of a detail of the testing head having cantilever probes of FIG. 1;

FIG. 5 is a sectional view of a detail of an embodiment of a testing head having cantilever probes according to the prior art;

FIGS. 6A and 6B are respective schematic views of an embodiment of a testing head having cantilever probes according to the prior art;

FIGS. 7A and 7B are respective schematic views of a further embodiment of cantilever probes according to the prior art;

FIGS. 8A and 8B are respective schematic views of an embodiment of cantilever probes according to an embodiment of the invention;

FIGS. 9A to 9E are schematic views of further embodiments of the cantilever probes according to an embodiment of the invention; and

FIGS. 10A and 10B schematically show the operation of the contact probes according to an embodiment of the invention and of contact probes according to the prior art when compared to each other.

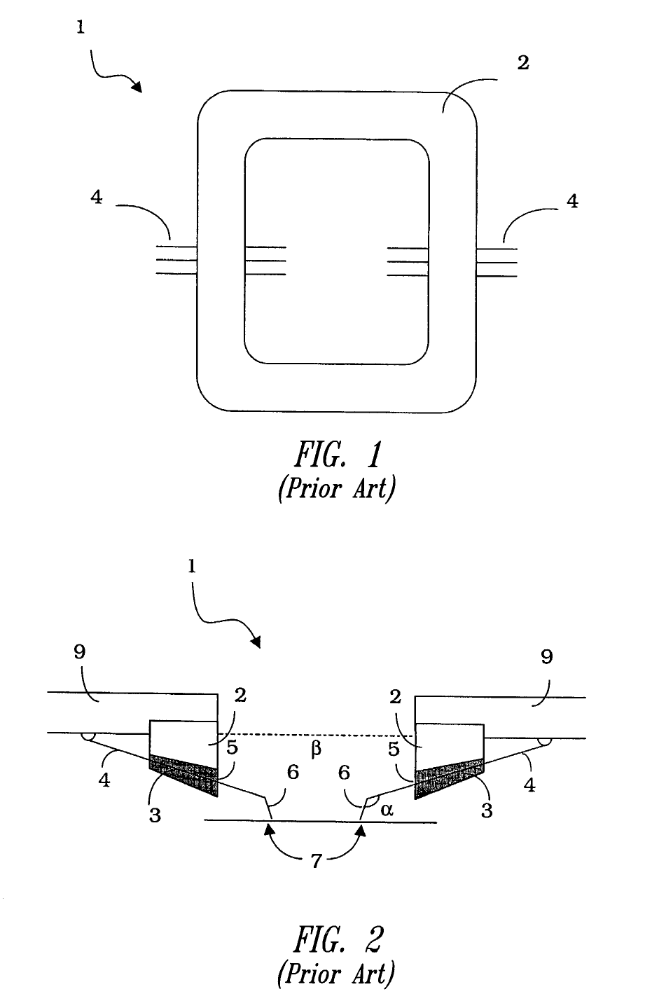

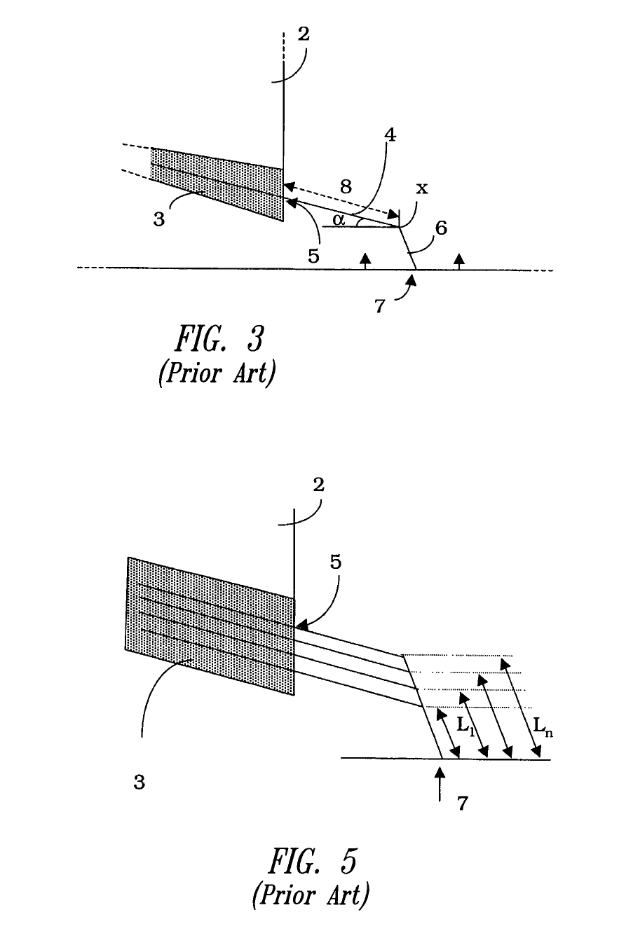

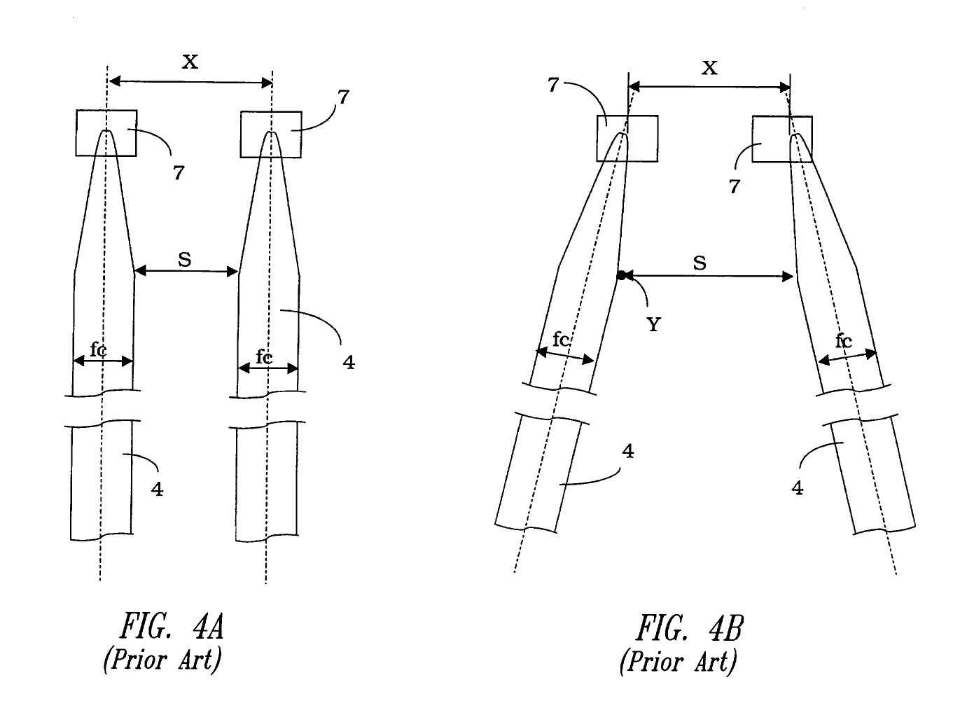

### DETAILED DESCRIPTION OF THE INVENTION

With reference in particular to FIGS. 8A and 8B, for convenience of illustration, shown is a testing head 11 comprising only four contact probes 14, being clearly understood that the testing head according to embodiments of the invention comprises any number of movable probes and that the invention is not limited to this embodiment, having instead a completely general character.

In addition, structurally and functionally identical elements with respect to the prior art have the same reference numbers, for convenience of illustration.

The testing head 11 comprises therefore a resin holder 13 capable to hold a plurality of cantilever contact probes 14.

Particularly, the contact probes 14 comprise pointed substantially rod-shaped bodies and have end portions called crooks 16, bent in correspondence with a so-called elbow points G1-G4, in order to contact a plurality of contact pads 7 of the device 10 being tested, the bonding between the contact probes 14 and these contact pads 7 being ensured by the pressure of the testing head 11 on the device 10. The contact probes 14 flex therefore vertically in the opposite direction from the device movement to the testing head.

The testing head 11 according to an embodiment of the invention comprises a plurality of contact probes 14 arranged in a plurality of levels L1-L4. Particularly, the testing head 11 shown in FIG. 8A comprises at least four probes 14 arranged to emerge from the holder 13, on four levels L1, . . . , L4 and having four crooks 16₁, . . . , 16₄ respectively.

Advantageously, the contact probes 14 further have, besides the starting elbow point G1, . . . , G4 of the crooks 16, an additional elbow point Gb1, . . . ,Gb4 located in a probe section 18 between the holder 13 and said crooks and defining a concave angle in the body of the probe 14.

Particularly, the probe body 14 descends at a high slope from the holder 13, and then it continues substantially parallel with the plane of the device to be tested up to the starting elbow point.

It is also possible to consider the case in which the probe body goes back to the elbow point G1 starting from the additional elbow point Gb1, in a more or less sloped way with respect to the plane of the device to be tested.

In this way, it is possible to reduce the lengths of the crooks 16, spacing thereby the collision risk points, thus overcoming a serious drawback of the prior art solutions. In fact, the crook starting elbow points are nearer to the tips of the contact probes 14 and therefore more spaced to each other.

Generally, the elbow points can form live angle, curvilinear or circle arch junctions between the probe adjacent sections.

A further preferred embodiment of the invention, to avoid too acute elbow points, further provides additional elbow points Gc2, Gc4 capable to define a plurality of probe sections 18A, 18B, advantageously bent in the same direction as the crooks 16 to further reduce the length.

In the example of FIG. 8A, the probe of level L2 has therefore a first additional elbow point Gb2 in the first probe section 18A, a second additional elbow point Gc2 before the starting elbow point G2 of the crook 16₂ to create the second probe section 18B. The length of the crook 16₂ of this probe is equalized to a length I1 of the crook 16₁ of the probe of level L1, as shown in FIG. 8B.

Similarly, the probe of level L3 has therefore a first additional elbow point Gb3 in the probe section 18, after the starting elbow point G3 of the crook 16₃, in order to reduce the length of the crook 16₃ at a length I2 higher than the length I1 of the crook 16₁ and 16₂ of the probes of level L1 and L2, but lower than the length I3 of the crook of level L3 produced according to the prior art.

Finally, the probe of level L4 has a first additional elbow point Gb4 in the probe section 18A and a second additional elbow point Gc4 before the starting elbow point G4 of the crook 16₄ to create the second probe section 18B, in order to reduce the length of the crook 64 at the length I2 of the crook 16₃ of the probes of level L3.

The testing head shown in FIG. 8A has therefore crook starting elbow points only in correspondence with a first plane P1 and a second plane P2, with an increase of the distances between the probes and a subsequent reduction of collision risks.

More generally, the testing head 11 according to an embodiment of the invention comprises multi-ply contact probes 14 comprising a plurality of sections separated by elbow points in order to obtain a desired reduction of the length of the crooks of the different probe levels and of the probe collision risk, at least one of said sections being bent in the opposite direction as the crooks 16.

Taking to the limit the number of additional elbow points inserted, it is possible to produce substantially curvilinear probes.

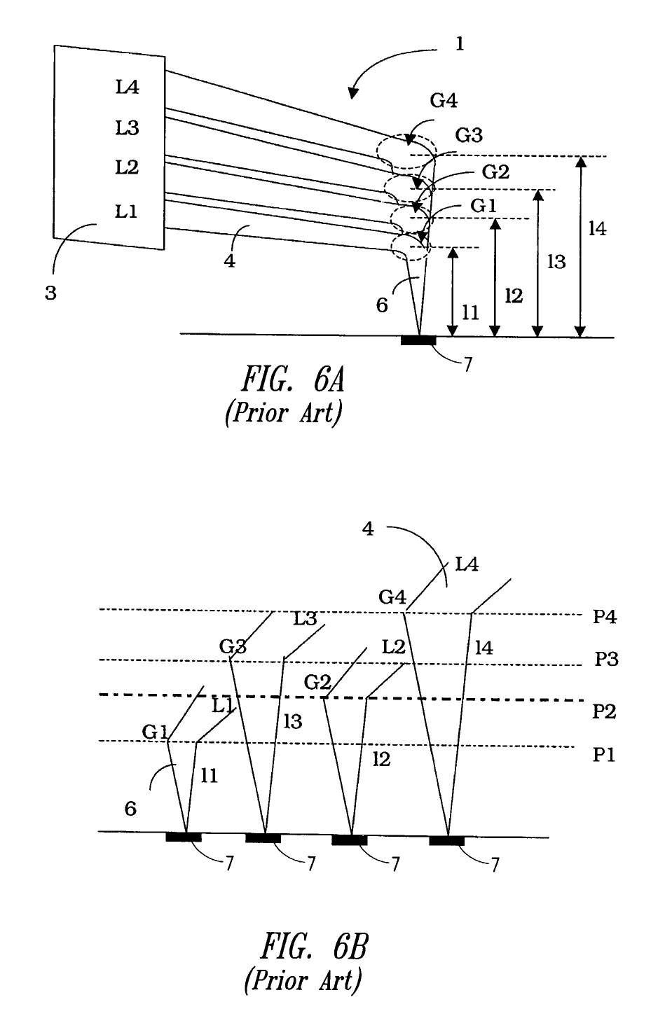

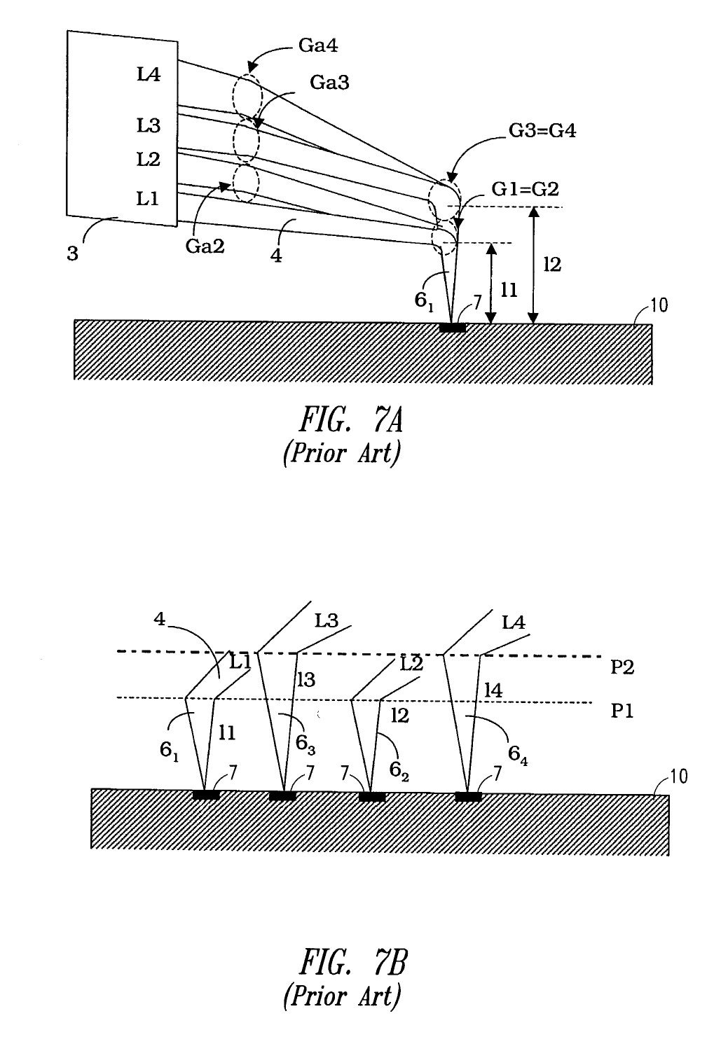

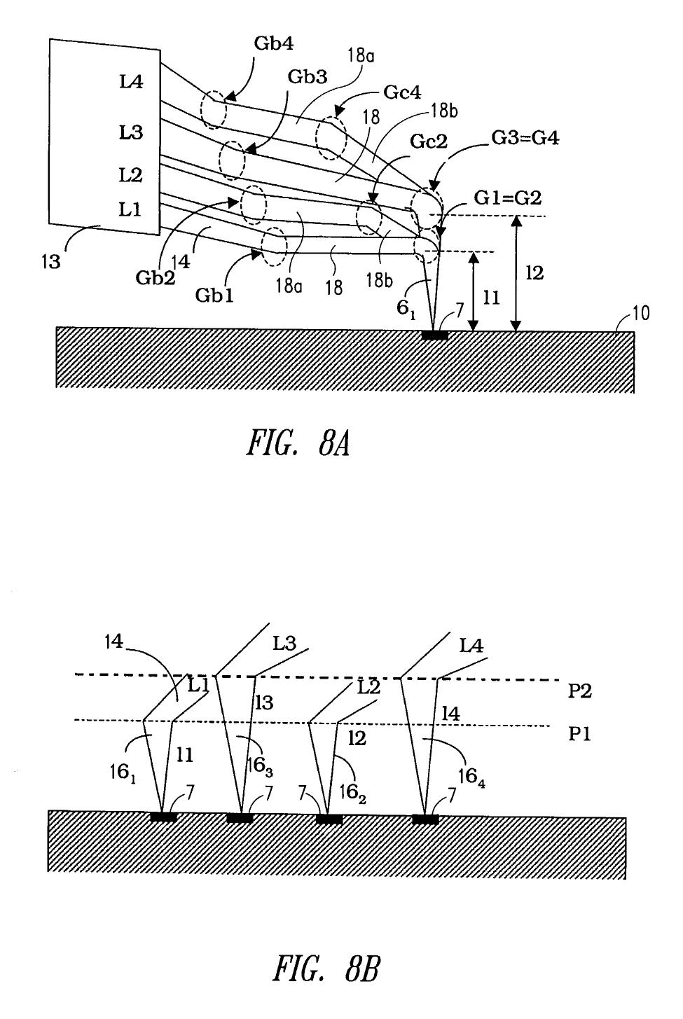

A testing head according to the prior art schematically shown in FIG. 6A and a testing head according to an embodiment of the invention schematically shown in FIG. 8A will now be compared. By considering the typical quantity values of the testing heads, the length of the known head crooks in FIG. 6A is between I1 =200 u and I4=500 u with distances of 100 u between the levels. In the case of the head 11 according to an embodiment of the invention only the crooks of length I1=I2=200 u and I3=I4=300 u are available.

It appears therefore how, in the case of the testing heads according to the prior art, the length of the crooks 6 increases rapidly as levels increase, particularly, in the example shown, by a value equal to additional 300 u for the three levels L2, L3, L4, while in the case of the technique according to an embodiment of the invention, the length of the crooks 16 increases only by additional 100 u for the same levels L2, L3, L4.

Generally, it can be stated that, while in the traditional technology each level Ln corresponds to a length In of the crook which is greater than the length In-1 of the crook of the lower level probe, the testing head according to an embodiment of the invention comprises several subsequent levels, Ln-1 and Ln, with crooks having the same length In-1 corresponding to the lowest level Ln-1.

Advantageously according to embodiments of the invention, the probe sections can be straight, curvilinear or mixed, each section having a suitable length, and jointed to each other in the most advantageous way to obtain the desired length crooks.

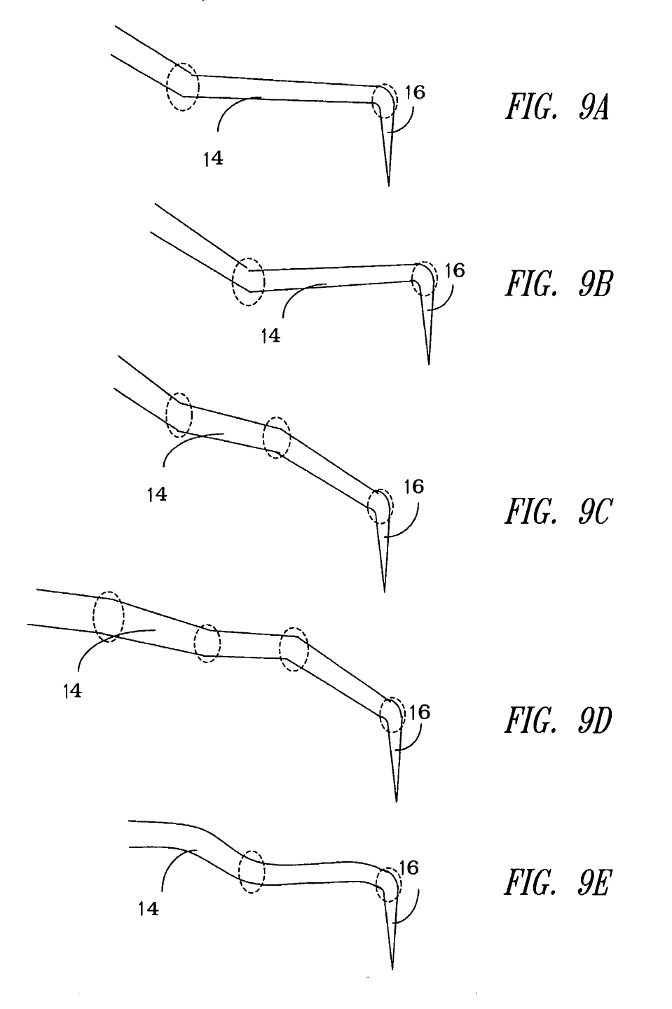

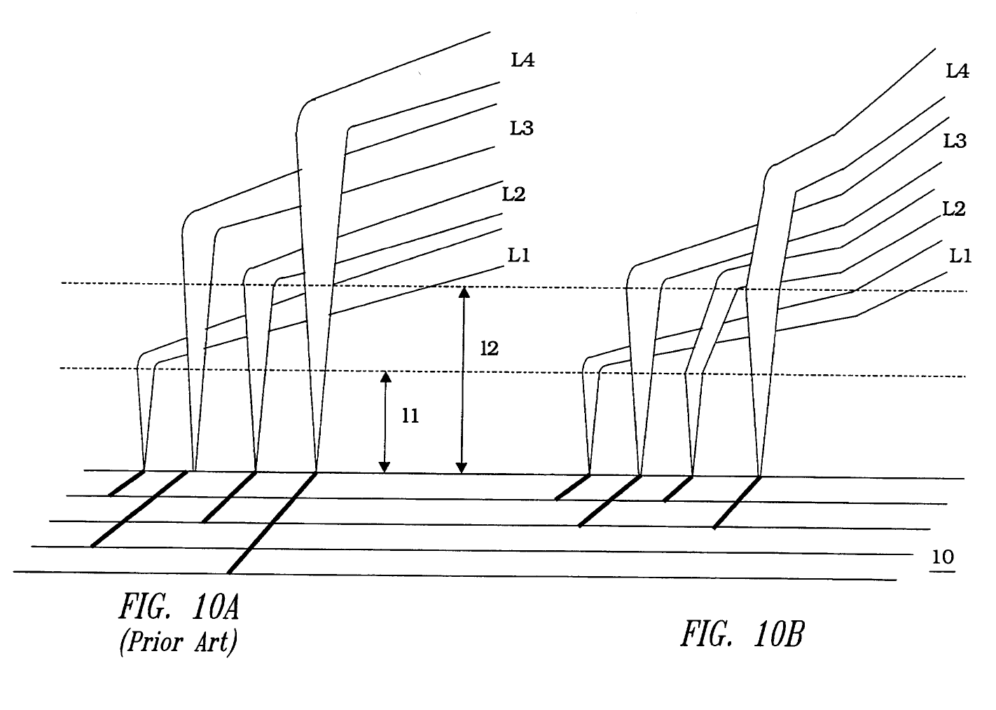

Some embodiments, given by way of non-limiting example, of multiply contact probes according to the invention are shown in FIGS. 9A and 9E.

These multiply probes can have one or more straight or curvilinear or mixed sections.

Advantageously according to embodiments of the invention, the multiple contact probes 14 can be gathered together, reducing the length of the crooks and spacing from each other, by means of suitable bending, the collision risk points.

The testing head according to embodiments of the invention, due to the reduction of the crook lengths, has the following additional advantages:

Possibility of using sturdier tips, i.e., tips with greater diameter, without risking the collision between adjacent probes.

In fact, with equal pitch and crook length In, the safety area S between the probes in the elbow point thereof is much greater in the case of multiple probes according to an embodiment of the invention with respect to the probes according to the traditional one-ply technique. This implies that, once the minimum safety distance S set, it is possible to use sturdier probes ensuring a greater pressure of the crooks on the contact pads and, therefore, a greater contact resistance, more reliable electric measures and higher selection yields.

Reduction of the crook length and, thus, of the scrub marks.

It can be easily noted that, when the levels, and thus the crook lengths, increase, the scrub mark length also increases almost proportionally.

FIGS. 10A and 10B schematically show the scrub marks obtained with a testing head according to the traditional technology (FIG. 10A) and those obtained with a testing head according to an embodiment of the invention with the multiply technique (FIG. 10B).

Particularly, it appears that the crook length reduction obtained by using the multiply technique reduces in a substantially proportional way the scrub mark value.

Damage reduction of the contact pads of the device to be tested.

In fact, it appears that, by reducing the scrub mark length by means of the multiply technique according to an embodiment of the invention, the damaged area of the contact pads is reduced. A better quality of the following bonding operations to be implemented on the device contact pads is thereby allowed.

Possibility of testing devices having smaller pitch with respect to the traditional testing heads.

In fact, it appears that, with the same size of the probes used, the testing head according to embodiments of the invention allows reduced pitch devices to be tested with high quality and reliability. The new technology requirements, asking for more and more reduced contact pads and pitch size, are therefore satisfied.

Possibility of reducing the contact pad size, and therefore, lower silicon consumption.

Due to the scrub mark reduction, it is possible to reduce the contact pad size, obtaining a considerable area gain; with the same silicon area it will be possible to produce a greater number of devices.

In conclusion, the testing head according embodiments of the invention allows:

a reduction of the crook length of the contact probes;

an increase in the probe diameter without risking a collision therebetween, improving therefore the contact resistance Rc;

a reduction of the scrub mark length for the same overdrive;

an increase in the contact pressure between probes and contact pads;

a reduction of the usable pitch value;

a reduction of the contact pad size to be used; and

an increase in the area between the probe and, therefore, easier manufacture and greater reliability of the whole testing head.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

Changes can be made to the invention in light of the above detailed description. In general, in the following claims, the terms used should not be construed to limit the invention to the specific embodiments disclosed in the specification and the claims, but should be construed to include all methods and devices that are in accordance with the claims. Accordingly, the invention is not limited by the disclosure, but instead its scope is to be determined by the following claims.

1. A contact probe for a testing head comprising a pointed rod-shaped body having a crook-shaped section capable to mechanically and electrically contact a contact pad of an electronic device to be tested and defined by an elbow point on the rod-shaped body and an additional elbow point spaced from the elbow point and defining a concave angle in the rod-shaped body.

2. The contact probe of claim 1, wherein the additional elbow point defines with the elbow point a probe section being substantially parallel to a plane of the electronic device to be tested.

3. The contact probe of claim 2, wherein the probe section is straight.

4. The contact probe of claim 2, wherein the probe section is curvilinear.

5. The contact probe of claim 1, wherein the additional elbow point defines with the elbow point a probe section bent in an opposite direction to the crook-shaped section.

6. The contact probe of claims 5, wherein the probe section is straight.

7. The contact probe of claim 5, wherein the probe section is curvilinear.

8. The contact probe of claim 1, wherein the rod-shaped body comprises a further additional elbow point defining a convex angle in the rod-shaped body.

9. The contact probe of claim 1, wherein the rod-shaped body comprises a plurality of additional elbow points capable to define a plurality of probe sections.

10. The contact probe of claim 9, wherein the plurality of probe sections comprises a straight section.

11. The contact probe of claim 9, wherein the plurality of probe sections comprises a curvilinear section.

12. The contact probe of claim 9, wherein the plurality of probe sections comprises straight and curvilinear sections.

13. The contact probe of claim 9, wherein the plurality of additional elbow points on the rod-shaped body is so dense that the rod-shaped body of the probe is substantially curvilinear.

14. The contact probe of claim 1, wherein the elbow points form live angle junctions between adjacent sections of the rod-shaped body of the probe.

15. The contact probe of claim 1, wherein the elbow points form curvilinear junctions between adjacent sections of the rod-shaped body of the probe.

16. The contact probe of claim 15, wherein the curvilinear junctions comprise circle arches.

17. A contact probe for a testing head comprising:
a pointed rod-shaped body;
a crook-shaped section starting from an elbow point on the pointed rod-shaped body and capable to mechanically and electrically contact a contact pad of an electronic device to be tested;
wherein the rod-shaped body further comprises an additional elbow point spaced from the elbow point and defining a concave angle in the rod-shaped body.

18. The contact probe of claim 17, wherein the additional elbow point defines with the elbow point a probe section being substantially parallel to a plane of the electronic device to be tested.

19. The contact probe of claim 18, wherein the probe section is straight or curvilinear.

20. The contact probe of claim 17, wherein the additional elbow point defines with the elbow point a probe section bent in an opposite direction to the crook-shaped section.

21. The contact probe of claims 20, wherein the probe section is straight or curvilinear.

22. The contact probe of claim 17, wherein the rod-shaped body comprises a further additional elbow point defining a convex angle in the rod-shaped body.

23. The contact probe of claim 17, wherein the rod-shaped body comprises a plurality of additional elbow points defining a plurality of probe sections.

24. The contact probe of claim 23, wherein the plurality of probe sections comprises a straight and/or a curvilinear section.

25. The contact probe of claim 23, wherein the plurality of additional elbow points on the rod-shaped body is so dense that the rod-shaped body of the probe is substantially curvilinear.

26. The contact probe of claim 17, wherein the elbow points form live angle or curvilinear junctions between adjacent sections of the rod-shaped body of the probe.

27. The contact probe of claim 26, wherein the curvilinear junctions comprise circle arches.

28. A testing head, comprising:
a holder;
a plurality of cantilevered, contact probes coupled to the holder and having a plurality of crook-shaped sections capable to ensure the mechanical and electrical contact with a plurality of contact pads of an electronic device to be tested, the crook-shaped sections starting from an elbow point on a respective pointed rod-shaped body of the contact probes, the rod-shaped body also having an additional elbow point spaced from the elbow point and defining a concave angle in the rod-shaped body.

29. The testing head of claim 28, wherein the additional elbow point defines with the elbow point a probe section being substantially parallel to a plane of the electronic device to be tested.

30. The testing head of claim 29, wherein the probe section is straight or curvilinear.

31. The testing head of claim 28, wherein the additional elbow point defines with the elbow point a probe section bent in the opposite direction to the crook-shaped section.

32. The testing head of claims 31, wherein the probe section is straight or curvilinear.

33. The testing head of claim 28, wherein the rod-shaped body comprises a further additional elbow point defining a convex angle in the rod-shaped body.

34. The testing head of claim 28, wherein the rod-shaped body comprises a plurality of additional elbow points defining a plurality of probe sections.

35. The testing head of claim 34, wherein the plurality of probe sections comprises a straight and/or a curvilinear section.

36. The contact probe of claim 34, wherein the plurality of additional elbow points on the rod-shaped body is so dense that the rod-shaped body of the probe is substantially curvilinear.

37. The testing head of claim 28, wherein the elbow points form live angle or curvilinear junctions between adjacent sections of the rod-shaped body of the probe.

38. The contact probe of claim 37, wherein the curvilinear junctions comprise circle arches.
